(19) United States
(12) Patent Application Publication
(10) Pub. No.: US 2019/0123262 A1
(43) Pub. Date: Apr. 25, 2019

(54) SEMICONDUCTOR MANUFACTURING APPARATUS, MEMORY DEVICE, AND METHOD OF MANUFACTURING THE MEMORY DEVICE

(71) Applicant: Samsung Electronics Co., Ltd., Suwon-si (KR)

(72) Inventors: Joon-myoung Lee, Anyang-si (KR); Jae-hoon Kim, Seoul (KR); Yong-sung Park, Suwon-si (KR); Se-chung Oh, Yongin-si (KR); Jun-ho Jeong, Hwaseong-si (KR)

(73) Assignee: Samsung Electronics Co., Ltd., Suwon-si (KR)

(21) Appl. No.: 15/993,862

(22) Filed: May 31, 2018

(30) Foreign Application Priority Data
Oct. 24, 2017 (KR) 10-2017-0138456

(51) Int. Cl. H01L 43/02; H01L 43/10; H01L 43/12; G11C 11/16

(52) U.S. Cl. CPC H01L 43/02; G11C 11/161; H01L 43/12; H01L 43/10

(57) ABSTRACT

Provided is a semiconductor manufacturing apparatus including a transfer chamber, a first process chamber connected to the transfer chamber, and a second process chamber connected to the transfer chamber. The transfer chamber may be configured to transfer a substrate. The first process chamber may be configured to perform a first oxidation process for oxidizing a metal layer on the substrate at a first temperature. The second process chamber may be configured to perform a second oxidation process for oxidizing a metal layer on the substrate at a second temperature higher than the first temperature.

### CROSS-REFERENCE TO RELATED APPLICATION

This application claims the benefit of Korean Patent Application No. 10-2017-0138456, filed on Oct. 24, 2017, in the Korean Intellectual Property Office, the disclosure of which is incorporated herein in its entirety by reference.

### BACKGROUND

Inventive concepts relate to a memory device, and more particularly, to a variable resistance memory device including a magnetic tunnel junction structure including magnetic transition metal.

As electronic products operate at higher speeds and consume lower power, fast read/write operations and low operating voltages are desired for semiconductor devices embedded in the electronic products. Research is actively being conducted into a variable resistance memory device using magnetic resistance characteristics of a magnetic tunnel junction. Particularly, the variable resistance memory device is non-volatile and thus is regarded as a next-generation memory device. Currently, research is actively being conducted into spin transfer torque-magnetic random access memory (STT-MRAM), which may be capable of increasing a recording density.

### SUMMARY

Inventive concepts provide a memory device and a method of manufacturing the memory device.

Inventive concepts also provide a semiconductor manufacturing apparatus for manufacturing the memory device.

According to an aspect of inventive concepts, a semiconductor manufacturing apparatus may include a transfer chamber, a first process chamber, and a second process chamber. The transfer chamber may be configured to transfer a substrate. The first process chamber may be connected to the transfer chamber and may be configured to perform a first oxidation process for oxidizing a metal layer on the substrate at a first temperature. The second process chamber may be connected to the transfer chamber and may be configured to perform a second oxidation process for oxidizing a metal layer on the substrate at a second temperature higher than the first temperature.

According to another aspect of inventive concepts, a semiconductor manufacturing apparatus may include a first process chamber, a second process chamber, and a transfer chamber. The first process chamber may be configured to operate at a first temperature. The second process chamber may be configured to operate at a second temperature that may be higher than the first temperature. A transfer chamber may be connected to the first process chamber and the second process chamber. The first process chamber may be configured to perform a first oxidation process for oxidizing a first metal layer on a substrate by injecting an oxygen gas into the first process chamber. The transfer chamber may be configured to transfer the substrate from the first process chamber to the second process chamber. The second process chamber may be configured to perform a second oxidation process for oxidizing a second metal layer provided on the oxidized first metal layer by injecting an oxygen gas into the second process chamber. The second metal layer may include a same material as the first metal layer.

According to another aspect of inventive concepts, a method of manufacturing a memory device may include forming a first magnetic layer on a substrate, forming a first metal layer on the first magnetic layer, oxidizing the first metal layer at a first temperature to form an oxidized first metal layer, forming a second metal layer on the oxidized first metal layer, and oxidizing the second metal layer at a second temperature higher than the first temperature. The second metal layer and the first metal layer may include a same material.

According to another aspect of inventive concepts, a memory device may include a lower magnetic layer, a tunnel barrier layer on the lower magnetic layer, and an upper magnetic layer on the tunnel barrier layer. The tunnel barrier layer may include a metal oxide layer and may have an oxygen density gradient along a thickness direction.

### BRIEF DESCRIPTION OF THE DRAWINGS

Embodiments of inventive concepts will be more clearly understood from the following detailed description taken in conjunction with the accompanying drawings in which:

FIG. 1 is a cross-sectional view of a magnetic tunnel junction layer of a memory device, according to some embodiments of inventive concepts;

FIG. 2 is a schematic view showing the configuration of a memory device including the magnetic tunnel junction layer of FIG. 1;

FIG. 3 is a flowchart of a method of manufacturing a magnetic tunnel junction layer of a memory device, according to some embodiments of inventive concepts;

FIGS. 4A to 4F are cross-sectional views for describing the method of manufacturing the magnetic tunnel junction layer of the memory device, according to some embodiments of inventive concepts;

FIGS. 5A and 5B are cross-sectional views for describing a part of a method of manufacturing a magnetic tunnel junction layer of a memory device, according to other embodiments of inventive concepts;

FIGS. 6A and 6B are cross-sectional views for describing a part of a method of manufacturing a magnetic tunnel junction layer of a memory device, according to other embodiments of inventive concepts;

FIGS. 7A to 7F are cross-sectional views for describing a method of manufacturing a memory device, according to some embodiments of inventive concepts;

FIG. 8 is a graph for describing characteristics of a memory device manufactured using a memory device manufacturing method according to some embodiments of inventive concepts;

FIG. 9 is a schematic diagram of a semiconductor manufacturing apparatus according to some embodiments of inventive concepts;

FIG. 10 is a schematic diagram of a semiconductor manufacturing apparatus according to other embodiments of inventive concepts;

FIG. 11 is a schematic diagram of a semiconductor manufacturing apparatus according to other embodiments of inventive concepts; and

FIG. 12 is a cross-sectional view of a process chamber of a semiconductor manufacturing apparatus, according to some embodiments of inventive concepts.

### DETAILED DESCRIPTION OF EMBODIMENTS

Hereinafter, inventive concepts will be described in detail by explaining embodiments of inventive concepts with reference to the attached drawings. Like reference numerals in the drawings denote like elements, and thus repeated descriptions thereof will be omitted.

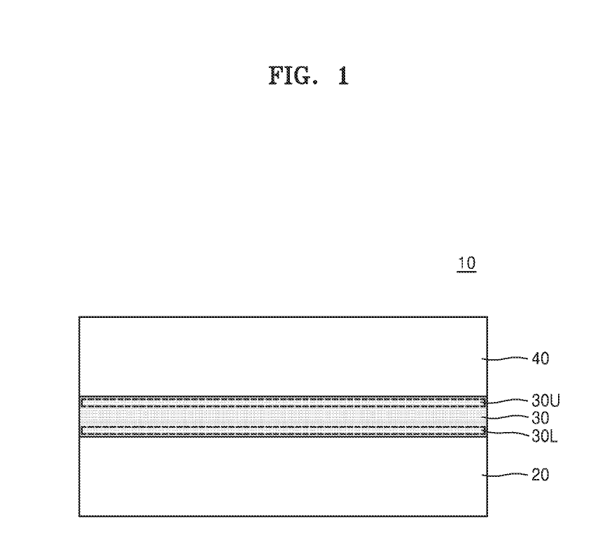

FIG. 1 is a cross-sectional view of a magnetic tunnel junction layer 10 of a memory device, according to some embodiments of inventive concepts.

Referring to FIG. 1, the magnetic tunnel junction layer 10 may include a first magnetic layer 20, a second magnetic layer 40, and a tunnel barrier layer 30 disposed between the first and second magnetic layers 20 and 40.

The first magnetic layer 20 may include a pinned layer having a fixed magnetization direction. For example, the pinned layer may have perpendicular magnetic anisotropy indicating that the magnetization direction is fixed in any perpendicular direction, e.g., a direction perpendicular to an extension direction of the pinned layer, or in-plane magnetic anisotropy indicating that the magnetization direction is fixed in any in-plane direction, e.g., a direction parallel to the extension direction of the pinned layer.

The second magnetic layer 40 may include a free layer having a variable magnetization direction. The magnetization direction of the free layer may vary depending on a magnetic field applied thereto. The free layer may have perpendicular magnetic anisotropy or in-plane magnetic anisotropy.

A resistance value may be determined based on whether the magnetization direction of the free layer and the magnetization direction of the pinned layer are parallel or antiparallel to each other. When the magnetic field that is externally applied to the second magnetic layer 40 is gradually increased to a switching field corresponding to a threshold value for magnetization reversal, the resistance value may be instantaneously changed due to a magnetization reversal phenomenon.

The free layer and the pinned layer may have the same type of magnetic anisotropic. For example, when the free layer has in-plane magnetic anisotropy, the pinned layer may also be made of a material having in-plane magnetic anisotropy. Otherwise, when the free layer has perpendicular magnetic anisotropy, the pinned layer may also be made of a material having perpendicular magnetic anisotropy.

The tunnel barrier layer 30 may be disposed between the first and second magnetic layers 20 and 40 and a quantum tunneling phenomenon may occur therein. The tunnel barrier layer 30 may include metal oxide having insulating properties. For example, the tunnel barrier layer 30 may include magnesium oxide (MgO) or aluminum oxide (AlOx). The tunnel barrier layer 30 may have a small thickness of about 1 Å to about 100 Å, but is not limited thereto.

In some embodiments, the tunnel barrier layer 30 may be made of metal oxide and may have an oxygen density gradient, which indicates a variation in oxygen density, in a thickness direction thereof, e.g., a direction perpendicular to an extension direction of the tunnel barrier layer 30. For example, the tunnel barrier layer 30 may have a lower part 30L in contact with the first magnetic layer 20 and an upper part 30U in contact with the second magnetic layer 40, and an oxygen density of the upper part 30U may be greater than the oxygen density of the lower part 30L.

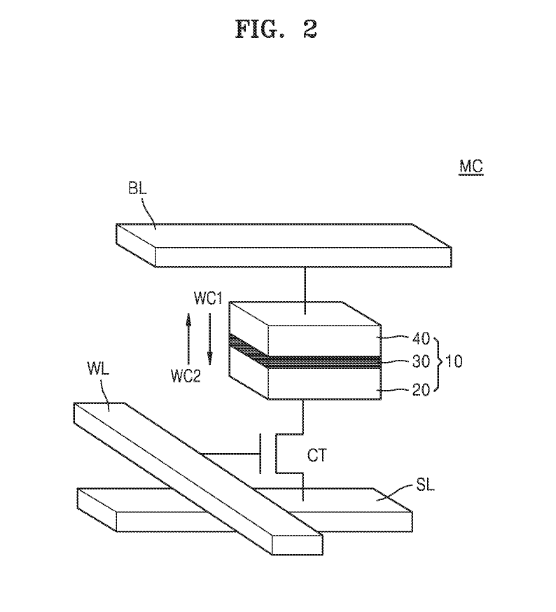

FIG. 2 is a schematic view showing the configuration of a memory device including the magnetic tunnel junction layer 10 of FIG. 1.

Referring to FIG. 2, a unit memory cell MC configured as spin transfer torque-magnetic random access memory (STT-MRAM) is shown.

The unit memory cell MC may include the magnetic tunnel junction layer 10 and a cell transistor CT. A gate of the cell transistor CT may be connected to a word line WL. Any electrode of the cell transistor CT may be connected through the magnetic tunnel junction layer 10 to a bit line BL, and the other electrode thereof may be connected to a source line SL.

The magnetic tunnel junction layer 10 may include the first magnetic layer 20 including a pinned layer having a fixed magnetization direction and the second magnetic layer 40 including a free layer having a variable magnetization direction depending on a condition. A resistance value of the magnetic tunnel junction layer 10 may vary depending on the magnetization direction of the free layer. When the magnetization direction of the free layer and the magnetization direction of the pinned layer are parallel to each other, the magnetic tunnel junction layer 10 may have a relatively low resistance value and may store data ‘0’. Otherwise, when the magnetization direction of the free layer and the magnetization direction of the pinned layer are antiparallel to each other, the magnetic tunnel junction layer 10 may have a relatively high resistance value and may store data ‘1’.

In some embodiments, for a write operation of the STT-MRAM, the unit memory cell MC may apply a logic high voltage to the word line WL to turn on the cell transistor CT, and apply a write current WC1 or WC2 between the bit line BL and the source line SL. The magnetization direction of the free layer may be determined based on a direction of the write current WC1 or WC2. The magnetization direction of the free layer in the magnetic tunnel junction layer 10 may be changed due to spin transfer torque. That is, the magnetic tunnel junction layer 10 may perform a memory function by using a spin transfer torque phenomenon in which a magnetization direction of a magnetic substance is variable depending on an input current.

In some embodiments, for a read operation of the STT-MRAM, the unit memory cell MC may apply a logic high voltage to the word line WL to turn on the cell transistor CT, and apply a read current from the bit line BL toward the source line SL to read data stored in the magnetic tunnel junction layer 10. Since an intensity of the read current is much less than the intensity of the write current WC1 or WC2, the magnetization direction of the free layer is not changed due to the read current.

Although the first magnetic layer 20 has a pinned layer and the second magnetic layer 40 has a free layer in FIG. 2, unlike this, the first magnetic layer 20 may have a free layer and the second magnetic layer 40 may have a pinned layer.

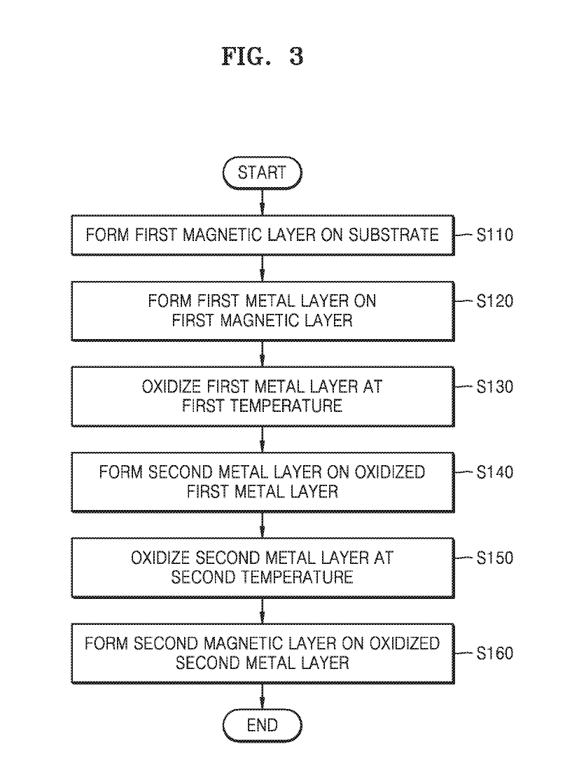

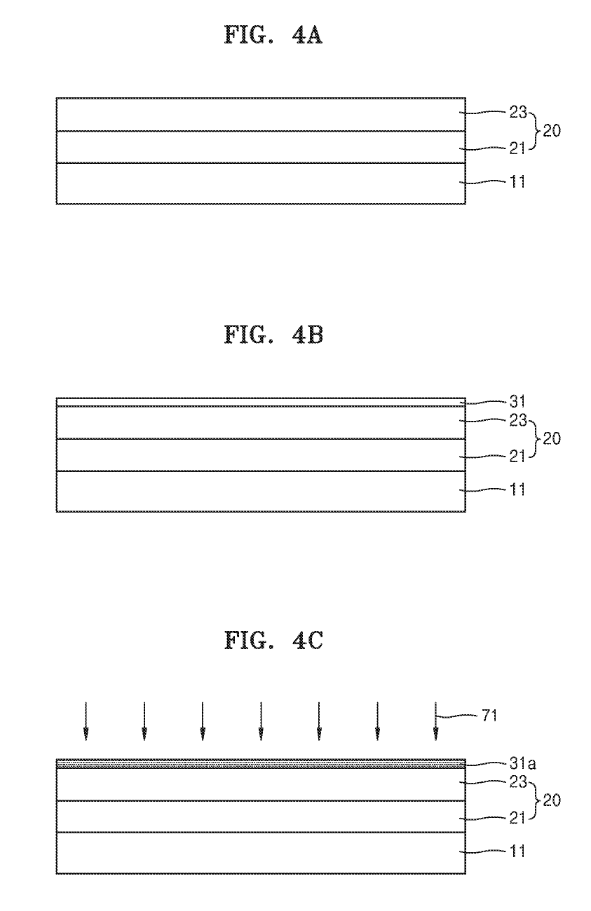

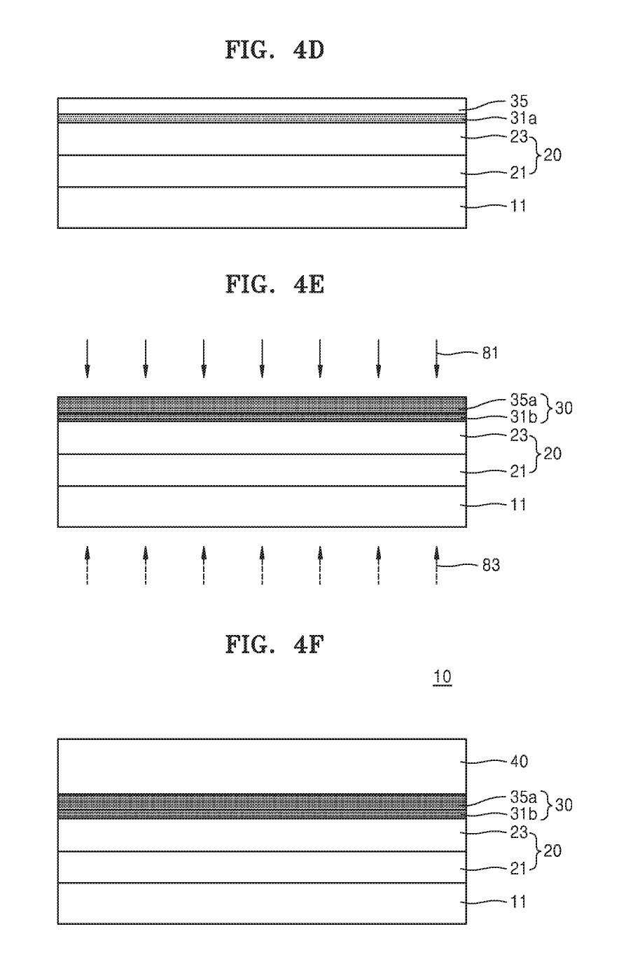

FIG. 3 is a flowchart of a method of manufacturing a magnetic tunnel junction layer 10 of a memory device, according to some embodiments of inventive concepts, and FIGS. 4A to 4F are cross-sectional views for describing the method of manufacturing the magnetic tunnel junction layer 10 of the memory device, according to some embodiments of inventive concepts.

Referring to FIGS. 3 and 4A, the first magnetic layer 20 is formed on a substrate 11 (S110). To form the first magnetic layer 20, a seed layer 21 and a pinned layer 23 may be sequentially formed on the substrate 11.

The seed layer 21 may include at least one of tantalum (Ta), ruthenium (Ru), and/or alloys thereof. For example, the seed layer 21 may be formed by using one of the above-mentioned materials or by stacking two or more of the above-mentioned materials. The seed layer 21 may aid growing of the pinned layer 23, and may promote crystallization of the pinned layer 23.

The pinned layer 23 may include a magnetic material including transition metal. The pinned layer 23 may include at least one of palladium (Pd), cobalt (Co), platinum (Pt), iron (Fe), ruthenium (Ru), tantalum (Ta), nickel (Ni), boron (B), manganese (Mn), antimony (Sb), aluminum (Al), chromium (Cr), molybdenum (Mo), silicon (Si), copper (Cu), iridium (Ir), and/or alloys thereof. Materials usable for the pinned layer 23 may include, for example, cobalt-iron (CoFe), nickel-iron (NiFe), and/or cobalt-iron-boron (CoFeB), but are not limited thereto. The pinned layer 23 may be formed by using one of the above-mentioned materials or by stacking two or more of the above-mentioned materials.

Referring to FIGS. 3 and 4B, after the first magnetic layer 20 is formed, a first metal layer 31 is formed on the first magnetic layer 20 (S120). The first metal layer 31 may include a metal for forming a tunnel barrier layer and may be made of, for example, magnesium (Mg) or aluminum (Al). In some embodiments, the first metal layer 31 may be formed to have a thickness between 1 Å and 5 Å.

To form the first metal layer 31, a physical vapor deposition (PVD) process or a chemical vapor deposition (CVD) process may be used. In some embodiments, the first metal layer 31 may be formed by a sputtering process.

Referring to FIGS. 3 and 4C, after the first metal layer (31 of FIG. 4B) is formed, the first metal layer is oxidized at a first temperature (S130). As the first metal layer is oxidized, a first interlayer 31a including metal oxide obtained due to oxidation of a part of the metal included in the first metal layer may be formed.

The first temperature may be in a range that is greater than or equal to 20° C. and less than 50° C., but is not limited thereto. For example, the first temperature may be room temperature. The oxidation process for oxidizing the first metal layer may be performed in a certain oxidation atmosphere 71 including an oxygen gas and an inert gas for controlling a pressure of the oxidation process. In some embodiments, in the oxidation process for oxidizing the first metal layer, the oxygen gas may be supplied into a chamber for the oxidation process at a flow rate between 0.01 sccm and 10 sccm.

Since the first metal layer is oxidized at the oxidation atmosphere 71 having a relatively low temperature and a relatively low oxygen flow rate, only a part of the metal included in the first metal layer may be oxidized. For example, when the first metal layer is made of magnesium (Mg), the first interlayer 31a may include magnesium (Mg) and magnesium oxide (MgO).

Referring to FIGS. 3 and 4D, a second metal layer 35 is formed on the oxidized first metal layer, e.g., the first interlayer 31a (S140). The second metal layer 35 may be made of, for example, magnesium (Mg) and/or aluminum (Al). In some embodiments, the second metal layer 35 may be made of a material that is the same as the material of the first metal layer (31 of FIG. 4B). The second metal layer 35 may be formed to have a thickness greater than the thickness of the first metal layer 31, e.g., a thickness between 10 Å and 100 Å.

To form the second metal layer 35, a PVD process or a CVD process may be used. In some embodiments, the second metal layer 35 may be formed by a sputtering process.

Referring to FIGS. 3 and 4E, after the second metal layer (35 of FIG. 4D) is formed, the second metal layer 35 is oxidized at a second temperature higher than the first temperature (S150). As the second metal layer (35 of FIG. 4D) is oxidized, a second interlayer 35a including metal oxide obtained due to oxidation of a part of the metal included in the second metal layer 35 may be formed. The second interlayer 35a and a first interlayer 31b may form a tunnel barrier layer 30.

The second temperature may be, for example, between 50° C. and 400° C. In some embodiments, the second temperature may be between 100° C. and 200° C. For example, to perform the oxidation process for oxidizing the second metal layer 35 at the second temperature, heat 83 may be applied to the substrate 11.

The oxidation process for oxidizing the second metal layer 35 may be performed in a certain oxidation atmosphere 81 including an oxygen gas and an inert gas for controlling a pressure of the oxidation process. In the oxidation process for oxidizing the second metal layer 35, the oxygen gas may be supplied into a chamber for the oxidation process at a flow rate between 0.1 sccm and 100 sccm.

The second metal layer 35 may be oxidized at the oxidation atmosphere 81 having a relatively high temperature and a relatively high oxygen flow rate. Accordingly, a rate by which the metal included in the second metal layer 35 is oxidized into metal oxide due to the oxidation process for oxidizing the second metal layer 35 may be higher than the rate by which the metal included in the first metal layer (31 of FIG. 4B) is oxidized into metal oxide due to the oxidation process in S130.

In the oxidation process for oxidizing the second metal layer 35, oxygen may be diffused to the first interlayer 31b under the second metal layer 35. Accordingly, during the oxidation process for oxidizing the second metal layer 35, non-oxidized metal in the first interlayer 31a of FIG. 4D may be oxidized into metal oxide. Since the first interlayer 31b may be further oxidized during the high-temperature oxidation process, crystallinity of the tunnel barrier layer 30 may be increased and tunneling magnetoresistance ratio (TMR) characteristics may be enhanced.

According to inventive concepts, by forming the first interlayer (31a of FIG. 4C) having a low oxygen density before the high-temperature oxidation process for increasing crystallinity of the tunnel barrier layer 30, diffusion of oxygen to the first magnetic layer 20 during the high-temperature oxidation process may be reduced and/or prevented. That is, the first interlayer may serve as an oxidation barrier capable of reducing and/or preventing diffusion of oxygen to the first magnetic layer 20 in the high-temperature oxidation process for oxidizing the second metal layer (35 of FIG. 4D). Accordingly, oxidation of the first magnetic layer 20 in the high-temperature oxidation process may be reduced and/or prevented and thus dispersion between different memory devices on the substrate 11 may be reduced and/or prevented.

Referring to FIGS. 3 and 4F, after the oxidation process for oxidizing the second metal layer (35 of FIG. 4D) is performed, the second magnetic layer 40 is formed on the oxidized second metal layer, e.g., the second interlayer 35a (S160). The first magnetic layer 20, the tunnel barrier layer 30, and the second magnetic layer 40 may form the magnetic tunnel junction layer 10.

The second magnetic layer 40 may be a free layer and may include a magnetic material including transition metal. The free layer may include at least one of palladium (Pd), cobalt (Co), platinum (Pt), iron (Fe), ruthenium (Ru), tantalum (Ta), nickel (Ni), boron (B), manganese (Mn), antimony (Sb), aluminum (Al), chromium (Cr), molybdenum (Mo), silicon (Si), copper (Cu), iridium (Ir), and/or alloys thereof. Materials usable for the free layer may include, for example, cobalt-iron (CoFe), nickel-iron (NiFe), and cobalt-iron-boron (CoFeB). The free layer may be formed by using one of the above-mentioned materials or by stacking two or more of the above-mentioned materials.

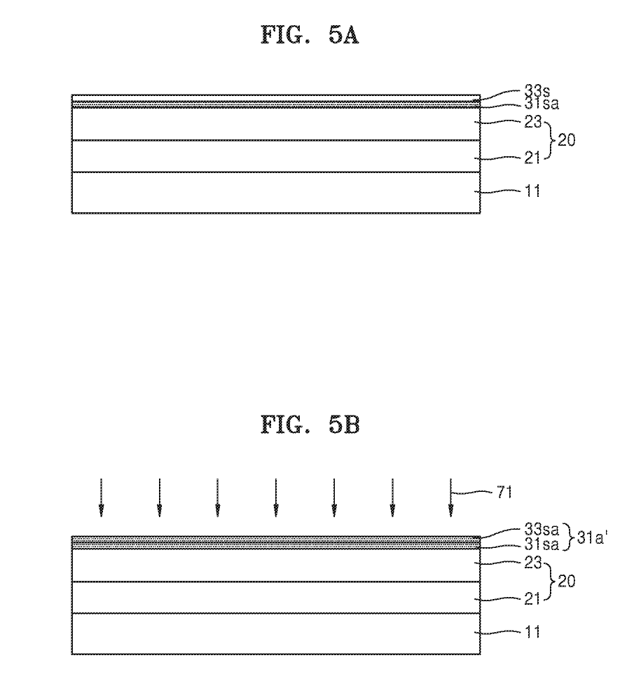

FIGS. 5A and 5B are cross-sectional views for describing a part of a method of manufacturing a magnetic tunnel junction layer of a memory device, according to other embodiments of inventive concepts.

Referring to FIG. 5A, the first magnetic layer 20 is formed on the substrate 11 by using the method described above in relation to FIG. 4A, and a first sub interlayer 31sa is formed on the first magnetic layer 20. The first sub interlayer 31sa may be formed by forming a first sub metal layer similarly to the method described above in relation to FIG. 4B to form the first metal layer (31 of FIG. 4B), and then oxidizing the first sub metal layer similarly to the method described above in relation to FIG. 4C to oxidize the first metal layer.

After the first sub interlayer 31sa is formed, a second sub metal layer 33s may be formed on the first sub interlayer 31sa. The second sub metal layer 33s may be formed similarly to the method described above in relation to FIG. 4B to form the first metal layer (31 of FIG. 4B).

Referring to FIG. 5B, a second sub interlayer 33sa may be formed by oxidizing the second sub metal layer (33s of FIG. 5A) in a certain oxidation atmosphere 71. The oxidation process for oxidizing the second sub metal layer may be performed under a condition similar to that of the oxidation process for forming the first interlayer 31a of FIG. 4C. The first and second sub interlayers 31sa and 33sa may form a first interlayer 31a′ for reducing and/or preventing diffusion of oxygen to the first magnetic layer 20 during a subsequent high-temperature oxidation process.

By repeatedly performing a metal layer deposition process and a metal layer oxidation process at least two times to form the first interlayer 31a′, diffusion of oxygen in a high-temperature oxidation process may be effectively blocked.

Herein, a metal layer deposition process and a metal layer oxidation process are sequentially and repeatedly performed two times to form the first interlayer 31a′. However, a metal layer deposition process and a metal layer oxidation process may be sequentially and repeatedly performed three or more times.

After the first interlayer 31a is formed, a second interlayer and a second magnetic layer may be formed by using the method described above in relation to FIGS. 4D to 4F, thereby forming the magnetic tunnel junction layer.

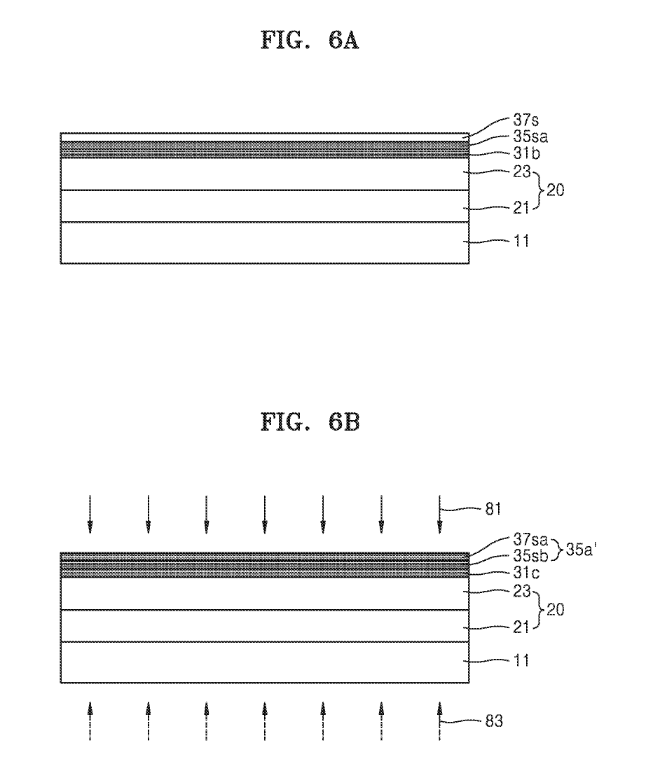

FIGS. 6A and 6B are cross-sectional views for describing a part of a method of manufacturing a magnetic tunnel junction layer of a memory device, according to other embodiments of inventive concepts.

Referring to FIG. 6A, the first magnetic layer 20 and an oxidized metal layer are formed on the substrate 11 by using the method described above in relation to FIGS. 4A to 4C, and a third sub interlayer 35sa is formed on the oxidized metal layer. The third sub interlayer 35sa may be formed by forming a third sub metal layer similarly to the method described above in relation to FIG. 4D to form the second metal layer (35 of FIG. 4D), and oxidizing the third sub metal layer similarly to the method described above in relation to FIG. 4E to oxidize the second metal layer 35. During the oxidation process for oxidizing the third sub metal layer, oxygen may be diffused to below the third sub metal layer and the oxidized metal layer may be further oxidized to form the first interlayer 31b.

After the third sub interlayer 35sa is formed, a fourth sub metal layer 37s may be formed on the third sub interlayer 35sa. The fourth sub metal layer 37s may be formed similarly to the method described above in relation to FIG. 4D to form the second metal layer (35 of FIG. 4D).

Referring to FIG. 6B, a fourth sub interlayer 37sa may be formed by oxidizing the fourth sub metal layer (37s of FIG. 6A) in a certain oxidation atmosphere 81. The oxidation process for oxidizing the fourth sub metal layer may be performed under a condition similar to that of the oxidation process described above in relation to FIG. 4E to form the second interlayer (35a of FIG. 4E). During the oxidation process for oxidizing the fourth sub metal layer, oxygen may be diffused to below the fourth sub metal layer, the third sub interlayer 35sa of FIG. 6A may be further oxidized to form a third sub interlayer 35sb, and the first interlayer 31b of FIG. 6A may be further oxidized to form a first interlayer 31c. The third and fourth sub interlayers 35sb and 37sa may form a second interlayer 35a′.

Herein, a metal layer deposition process and a metal layer oxidation process are sequentially and repeatedly performed two times to form the second interlayer 35a. However, a metal layer deposition process and a metal layer oxidation process may be sequentially and repeatedly performed three or more times.

After the second interlayer 35a′ is formed, a second magnetic layer may be formed by using the method described above in relation to FIG. 4F, thereby forming the magnetic tunnel junction layer.

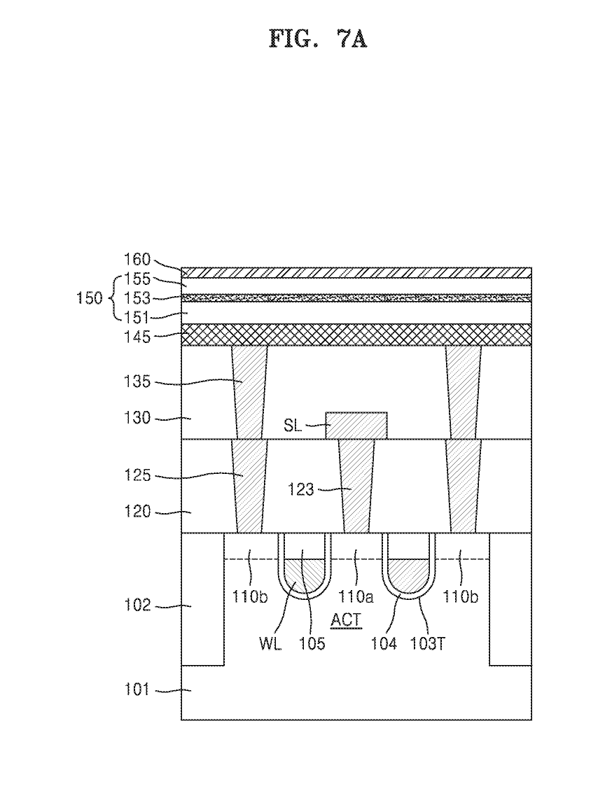

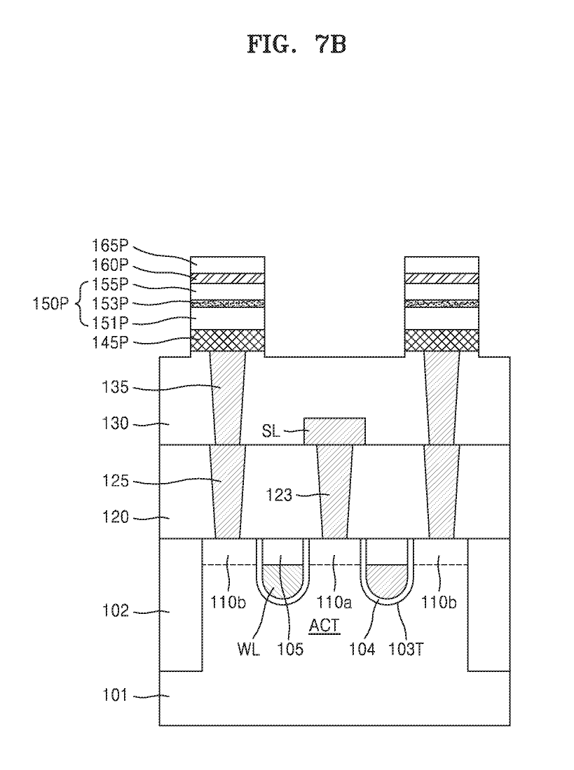

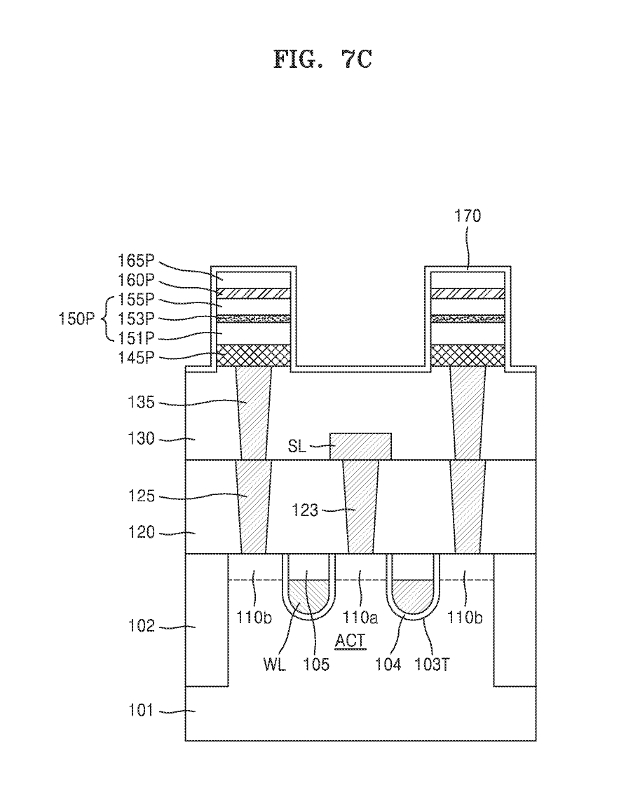

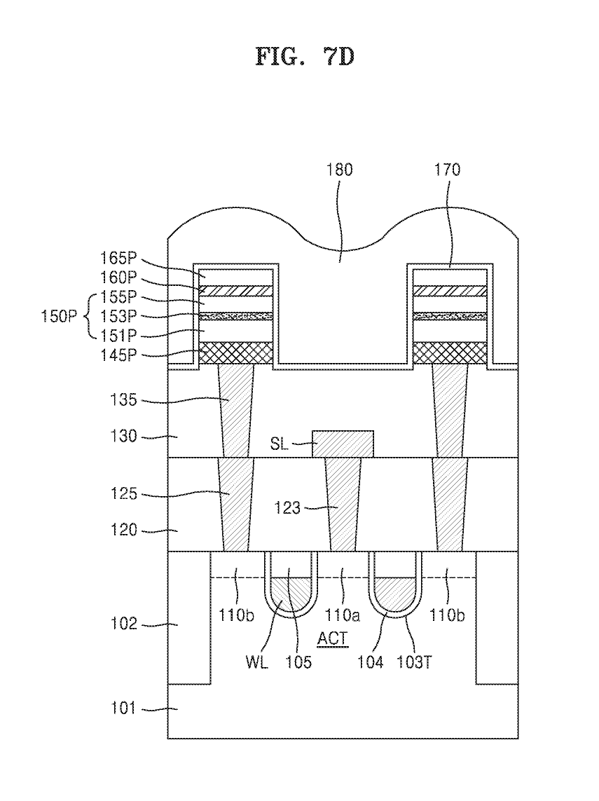

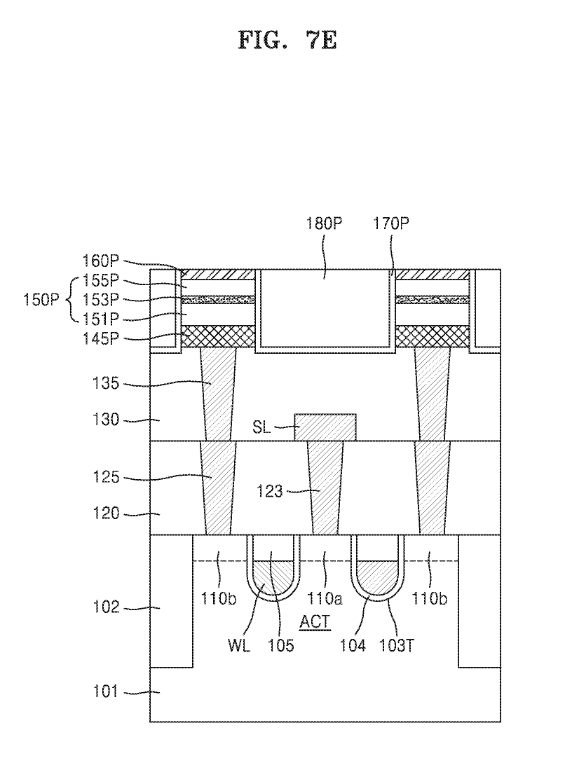

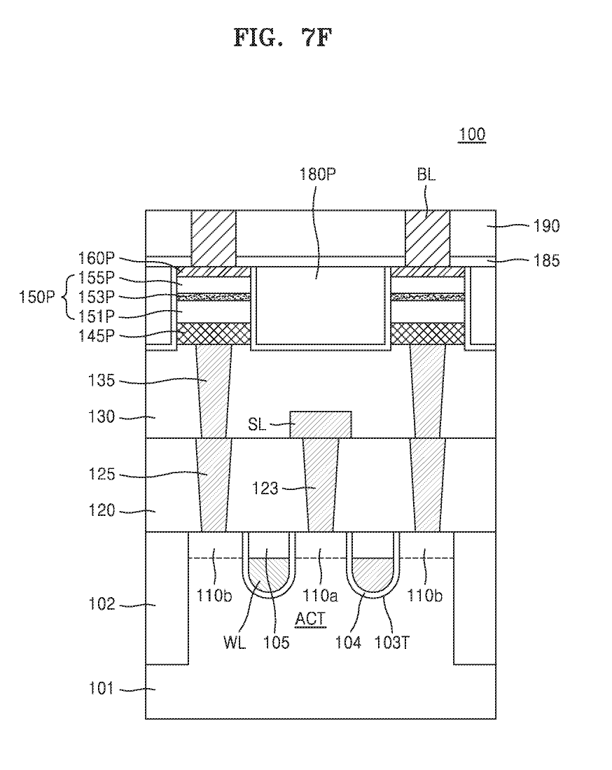

FIGS. 7A to 7F are cross-sectional views for describing a method of manufacturing a memory device, according to some embodiments of inventive concepts.

Referring to FIG. 7A, an active region ACT and word lines WL may be formed in a substrate 101. The substrate 101 may include silicon (Si), e.g., crystalline silicon, polycrystalline silicon, or amorphous silicon. Otherwise, the substrate 101 may include at least one of a semiconductor element such as germanium (Ge), Silicon germanium (SiGe), Silicon carbide (SiC), gallium arsenide (GaAs), indium arsenide (InAs), and/or indium phosphide (InP). Alternatively, the substrate 101 may include a silicon on insulator (SOI) structure. Alternatively, the substrate 101 may include a conductive region, e.g., a well doped with impurities or a structure doped with impurities.

The active region ACT may be defined by forming an isolation layer 102 in the substrate 101. The isolation layer 102 may be made of an insulating material. The isolation layer 102 may be formed by, for example, a shallow trench isolation (STI) process. The isolation layer 102 may be made of, for example, silicon oxide, silicon nitride, silicon oxynitride, or a combination thereof. The active region ACT may include first and second impurity regions 110a and 110b formed by ion-injecting impurities into upper parts of the active region ACT to a certain depth. The first and second impurity regions 110a and 110b may be formed to a depth smaller than that to bottom surfaces of the word lines WL. The first and second impurity regions 110a and 110b may serve as, for example, source/drain regions of a transistor formed by the word lines WL.

Then, the word lines WL may be formed in the active region ACT. A plurality of trenches 103T may be formed in the substrate 101, and then a gate insulating layer 104 and the word line WL made of a conductive material may be sequentially formed in each trench 103T. A gate capping layer 105 may be formed on the word line WL to fill a remaining space of the trench 103T. The word line WL may be formed in the trench 103T, and a level of a top surface of the word line WL may be lower than that of the top surface of the active region ACT.

Herein, a buried channel array transistor (BCAT) including buried word lines WL is described as an example. However, in other embodiments, the transistor structure may be modified into a planar transistor, a recess channel array transistor (RCAT), a sphere-shaped recess channel array transistor (SRCAT), or the like, but is not limited thereto.

Then, a first interlayer dielectric layer 120 and first and second contact plugs 123 and 125 may be formed on the substrate 101 in which the active region ACT and the word lines WL are formed.

The first interlayer dielectric layer 120 may include silicon oxide. Alternatively, the first interlayer dielectric layer 120 may include at least one of boro-phospho-silicate glass (BPSG), tonen silazene (TOSZ), undoped silicate glass (USG), spin-on glass (SOG), flowable oxide (FOX), tetraethylortho silicate (TEOS), and/or high density plasma chemical vapor deposition (HDP-CVD) oxide.

By removing parts of the first interlayer dielectric layer 120 by an exposure process and an etching process, contact holes penetrating through the first interlayer dielectric layer 120 may be formed. Thereafter, a conductive material may be formed on the first interlayer dielectric layer 120 to fill the contact holes, and may be partially removed by a planarization process such as a chemical mechanical polishing process or an etch-back process so that a top surface of the first interlayer dielectric layer 120 is exposed, thereby forming the first and second contact plugs 123 and 125 contacting the first and second impurity regions 110a and 110b. The first and second contact plugs 123 and 125 may include at least one of, for example, doped silicon, tungsten (W), aluminum (Al), titanium (Ti), tantalum (Ta), titanium nitride (TiN), tantalum nitride (TaN), tungsten nitride (WN), and/or metal silicide.

Then, a source line SL may be formed by forming a conductive material on the first interlayer dielectric layer 120 to contact the first contact plug 123 and patterning the conductive material. The conductive material may include at least one of doped poly silicon, metal silicide, metal, and/or metal nitride.

Then, a second interlayer dielectric layer 130 may be formed on the first interlayer dielectric layer 120 to cover the source line SL. The second interlayer dielectric layer 130 may be made of a material that is the same as or similar to that of the first interlayer dielectric layer 120. Contact holes may be formed to expose at least parts of top surfaces of the second contact plugs 125 by removing parts of the second interlayer dielectric layer 130. Third contact plugs 135 may be formed to contact the second contact plugs 125 by forming a conductive material in the contact holes and performing a planarization process. The third contact plugs 135 may be made of a material that is the same as or similar to that of the second contact plugs 125.

Then, a lower electrode 145 may be formed to cover the third contact plugs 135 and the second interlayer dielectric layer 130. The lower electrode 145 may include a conductive material such as at least one of titanium (Ti), tantalum (Ta), ruthenium (Ru), titanium nitride (TiN), tantalum nitride (TaN), or tungsten (W). In some embodiments, the lower electrode 145 may have a double layer structure of ruthenium/titanium, ruthenium/tantalum, ruthenium/titanium nitride, ruthenium/tantalum nitride, titanium nitride/tungsten, or the like. The lower electrode 145 may be formed by an atomic layer deposition (ALD) process, a CVD process, or the like.

Then, a magnetic tunnel junction layer 150 and a capping electrode layer 160 may be sequentially formed on the lower electrode 145. The magnetic tunnel junction layer 150 may be formed by using the method described above in relation to FIGS. 4A to 4F, the method described above in relation to FIGS. 5A and 5B, or the method described above in relation to FIGS. 6A and 6B.

In some embodiments, after the magnetic tunnel junction layer 150 is formed, a heat treatment process may be performed on the magnetic tunnel junction layer 150 to set a single desired magnetization direction of the magnetic tunnel junction layer 150. For example, the heat treatment process may be performed in a pressure range equal to or less than 0.1 mTorr and in a temperature range of 300° C. to 400° C. The heat treatment process may be performed in a gas atmosphere including at least one gas among hydrogen, oxygen, and/or nitrogen. In addition, an inert gas may be injected to control a pressure of the heat treatment process.

Referring to FIG. 7B, mask patterns 165P may be formed on the capping electrode layer (160 of FIG. 7A) to correspond to locations of the third contact plugs 135. The capping electrode layer (160 of FIG. 7A), a second magnetic layer (155 of FIG. 7A), a tunnel barrier layer (153 of FIG. 7A), a first magnetic layer (151 of FIG. 7A), and the lower electrode layer (145 of FIG. 7A) may be sequentially patterned by using the mask patterns 165P as an etching mask. Due to the patterning process, magnetic tunnel junction structures 150P including second magnetization patterns 155P, tunnel barrier patterns 153P, and first magnetization patterns 151P may be formed.

The mask patterns 165P may include silicon oxide, silicon nitride, silicon oxynitride, or the like. The patterning process may be performed by a dry etching process. Specifically, the patterning process may be performed by an ion beam etching process or a reactive ion etching process. During the etching process, parts of a top surface of the second interlayer dielectric layer 130, which are exposed between the magnetic tunnel junction structures 150P, may be recessed. Herein, the magnetic tunnel junction structures 150P have an etching profile having a constant cross-sectional area. In other embodiments, the magnetic tunnel junction structures 150P may have an etching profile having a gradually increasing cross-sectional area from an upper part to a lower part thereof.

Referring to FIG. 7C, a passivation layer 170 may be formed to cover lower electrode patterns 145P, the magnetic tunnel junction structures 150P, capping electrode patterns 160P, the mask patterns 165P, and the second interlayer dielectric layer 130. The passivation layer 170 may include, for example, metal oxide obtained due to oxidation of metals included in the magnetic tunnel junction structures 150P. The passivation layer 170 may be formed by an oxidation process, a CVD process, or the like.

The passivation layer 170 covering outer walls of the magnetic tunnel junction structures 150P may limit and/or prevent oxidation of the first and second magnetization patterns 151P and 155P.

Referring to FIG. 7D, an isolation insulation layer 180 may be formed on the passivation layer 170 to entirely fill spaces between the magnetic tunnel junction structures 150P. The isolation insulation layer 180 may be made of a material that is the same as or similar to that of the first interlayer dielectric layer 120.

Referring to FIG. 7E, isolation insulating patterns 180P and passivation patterns 170P may be formed and top surfaces of the capping electrode patterns 160P may be exposed by performing a planarization process to remove parts of the isolation insulation layer (180 of FIG. 7D) and the passivation layer (170 of FIG. 7D).

The planarization process may be performed by a chemical mechanical polishing process or an etch-back process. Due to the planarization process, the top surfaces of the capping electrode patterns 160P and top surfaces of the isolation insulating patterns 180P may have the same height. That is, the capping electrode patterns 160P may serve as an etch stop layer.

Referring to FIG. 7F, after the planarization process is completed, a top capping layer 185 and a third interlayer dielectric layer 190 may be sequentially formed to cover both of the top surfaces of the capping electrode patterns 160P and the top surfaces of the isolation insulating patterns 180P.

Subsequently, line-shaped mask patterns may be formed on the third interlayer dielectric layer 190, and then the third interlayer dielectric layer 190 and the top capping layer 185 may be partially etched, thereby forming line-shaped openings to expose the capping electrode patterns 160P.

Then, a conductive material may be formed to fill the openings and bit lines BL may be formed by a planarization process. A level of top surfaces of the bit lines BL may be the same as that of a top surface of the third interlayer dielectric layer 190. The bit lines BL may be made of metal having a low resistivity, e.g., copper (Cu).

Ultimately, the variable resistance memory device 100 may include the substrate 101, the isolation layer 102 in the substrate 101, the active region ACT defined in the substrate 101 by the isolation layer 102, the word lines WL buried in the substrate 101, and the source line SL and the magnetic tunnel junction structures 150P provided above the substrate 101.

The variable resistance memory device 100 may further include the first contact plug 123 for connecting the source line SL to the active region ACT, the second contact plugs 125 for connecting the active region ACT to the magnetic tunnel junction structures 150P, the lower electrode patterns 145P and the capping electrode patterns 160P provided in contact with the magnetic tunnel junction structures 150P, the third contact plugs 135 for connecting the lower electrode patterns 145P to the second contact plugs 125, and the bit lines BL connected to the capping electrode patterns 160P. The magnetic tunnel junction structures 150P may include the first magnetization patterns 151P, the tunnel barrier patterns 153P, and the second magnetization patterns 155P.

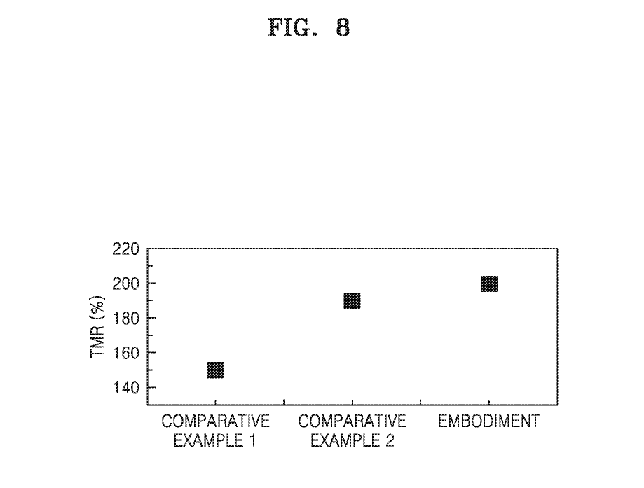

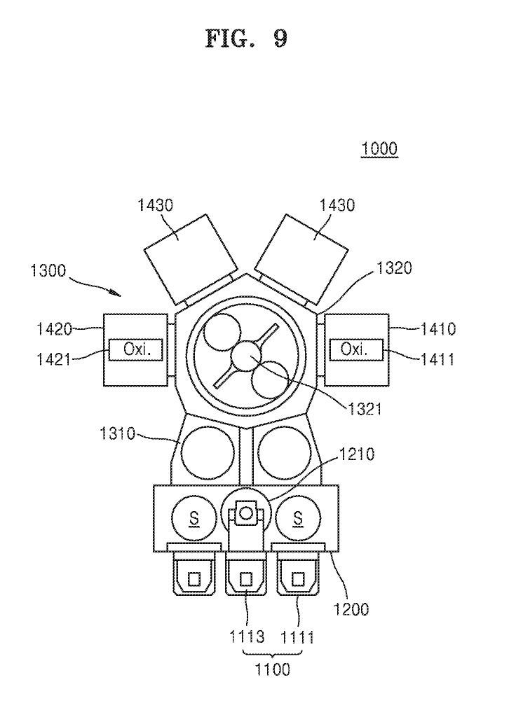

FIG. 8 is a graph for describing characteristics of a memory device manufactured using a memory device manufacturing method according to some embodiments of inventive concepts.

Referring to FIG. 8, TMR characteristics of memory devices according to comparative example 1, comparative example 2, and an embodiment are shown. Herein, the comparative example 1 indicates a memory device including a tunnel barrier layer formed by only an oxidation process at a first temperature corresponding to a relatively low temperature, and the comparative example 2 indicates a memory device including a tunnel barrier layer formed by only an oxidation process at a second temperature corresponding to a relatively high temperature. For example, the memory device according to the embodiment may be manufactured through manufacturing method described above with reference to FIGS. 3 to 7F. It is shown that the memory device according to the embodiment has improved TMR characteristics compared to the comparative examples 1 and 2.

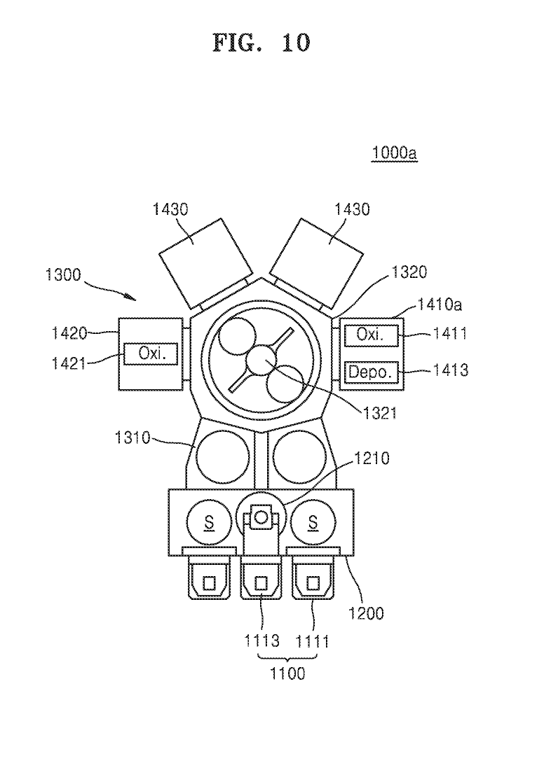

FIG. 9 is a schematic diagram of a semiconductor manufacturing apparatus 1000 according to some embodiments of inventive concepts.

Referring to FIG. 9, a cluster-type semiconductor manufacturing apparatus 1000 capable of processing a plurality of substrates S is shown. The cluster-type semiconductor manufacturing apparatus 1000 may refer to a multi-chamber substrate processing system including a transfer robot (or a handler) and a plurality of substrate processing modules provided around the transfer robot.

The semiconductor manufacturing apparatus 1000 may include a load port 1100, an equipment front end module 1200, and manufacturing process equipment 1300.

The load port 1100 may include a container 1113 provided at a front end of the equipment front end module 1200, and a container holder 1111 for supporting the container 1113. The container 1113 serves as a vessel for accommodating the substrates S, and an enclosed front opening unified pod (FOUP) may be used to protect the substrates S from foreign substances in the air or chemical contamination.

The equipment front end module 1200 may include a first transfer robot 1210 which operates at an atmospheric pressure. The first transfer robot 1210 may transfer each substrate S between the container 1113 and the manufacturing process equipment 1300.

The manufacturing process equipment 1300 may include a load lock chamber 1310, a transfer chamber 1320, and a plurality of process chambers (e.g., first to third process chambers 1410, 1420, and 1430).

The transfer chamber 1320 may include a second transfer robot 1321 which operates in a vacuum atmosphere and rotates freely. The transfer chamber 1320 may transfer the substrate S among the first to third process chambers 1410, 1420, and 1430, and transfer the substrate S between the first to third process chambers 1410, 1420, and 1430 and the load lock chamber 1310. The first to third process chambers 1410, 1420, and 1430 and the load lock chamber 1310 may be connected to sides of the transfer chamber 1320.

The load lock chamber 1310 may maintain a pressure by autonomously switching between a vacuum state and an atmospheric pressure in order to limit and/or prevent variations in a pressure state of the transfer chamber 1320. Although not shown in FIG. 9, a buffer stage for temporarily holding the substrate S may be mounted in the load lock chamber 1310. The load lock chamber 1310 may form a vacuum atmosphere equal to or close to that of the transfer chamber 1320 and receive an unprocessed substrate S from the equipment front end module 1200 when the second transfer robot 1321 of the transfer chamber 1320 loads or unloads the substrate S. Alternatively, the load lock chamber 1310 may maintain an atmospheric pressure state when a processed substrate S is transferred to the equipment front end module 1200. The substrate S processed by the manufacturing process equipment 1300 may be transferred into the load lock chamber 1310 of a vacuum state by the second transfer robot 1321 of the transfer chamber 1320. The substrate S transferred into the load lock chamber 1310 may be transferred into the container 1113 by using the first transfer robot 1210.

The first to third process chambers 1410, 1420, and 1430 may perform various semiconductor processes for manufacturing a memory device, and may be provided in a plural number.

The first process chamber 1410 may operate at a first temperature and may perform an oxidation process for oxidizing the substrate S. The first process chamber 1410 may include an oxidation unit 1411 for performing the oxidation process, and the oxidation unit 1411 may perform one of oxidation processes such as plasma oxidation, radical oxidation, and/or natural oxidation. For example, the oxidation unit 1411 may include a plasma generating device such as magnetron for generating O2 plasma.

The first process chamber 1410 may be configured to perform the oxidation process described above in relation to FIG. 4C to oxidize the first metal layer (31 of FIG. 4B). To perform the oxidation process for oxidizing the first metal layer, the first process chamber 1410 may form a temperature atmosphere of a first temperature (e.g., a temperature in range that is greater than or equal to 20° C. and less than 50° C.). The first temperature may be, for example, room temperature.

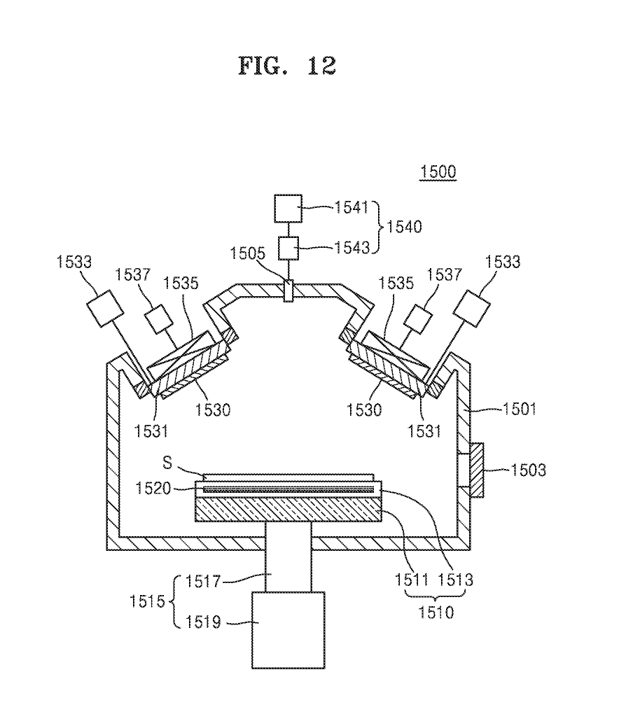

The first process chamber 1410 may include a first gas supplier (for example, see 1540 of FIG. 12) for supplying a process gas into the first process chamber 1410. In some embodiments, the first gas supplier may supply an oxygen gas into the first process chamber 1410 at a flow rate between 0.01 sccm and 10 sccm to perform the oxidation process for oxidizing the first metal layer.

The second process chamber 1420 may operate at a second temperature higher than the first temperature and may perform an oxidation process for oxidizing the substrate S. The second process chamber 1420 may include an oxidation unit 1421 for performing the oxidation process, and the oxidation unit 1421 may perform one of oxidation processes such as plasma oxidation, radical oxidation, and/or natural oxidation. For example, the oxidation unit 1421 may include a plasma generating device such as magnetron for generating O2 plasma.

The second process chamber 1420 may be configured to perform the oxidation process described above in relation to FIG. 4E to oxidize the second metal layer (35 of FIG. 4D). That is, to perform the oxidation process for oxidizing the second metal layer 35, the second process chamber 1420 may form a temperature atmosphere of a second temperature. The second temperature may be higher than the first temperature and may be, for example, between 50° C. and 400° C. In some embodiments, the second temperature may be between 100° C. and 200° C.

The second process chamber 1420 may include a heater (for example, see 1520 of FIG. 12) for forming a high-temperature atmosphere in the second process chamber 1420 or heating the substrate S. The heater may be provided, for example, in a chuck device for supporting the substrate S.

The second process chamber 1420 may include a second gas supplier (for example, see 1540 of FIG. 12) for supplying a process gas into the second process chamber 1420. In some embodiments, the second gas supplier may supply an oxygen gas into the second process chamber 1420 at a flow rate between 0.1 sccm and 100 sccm to perform the oxidation process for oxidizing the second metal layer 35.

The third process chamber 1430 may be configured to perform a deposition process for manufacturing a memory device. The third process chamber 1430 may deposit a metal layer on the substrate S and may perform a deposition process, e.g., a PVD process or a CVD process. The third process chamber 1430 may include a plurality of chambers for forming various types of material layers. In some embodiments, the third process chamber 1430 may include a sputtering device for performing a direct current (DC) sputtering process.

The third process chamber 1430 may be configured to perform, for example, the deposition process described above in relation to FIG. 4B to deposit the first metal layer (31 of FIG. 4B) and/or the deposition process described above in relation to FIG. 4D to deposit the second metal layer (35 of FIG. 4D). In some embodiments, when the third process chamber 1430 includes a sputtering device, the sputtering device may include a Mg target.

A magnetic tunnel junction layer manufacturing process using the semiconductor manufacturing apparatus 1000 may be performed as an in-situ process. That is, in the semiconductor manufacturing apparatus 1000 which maintains a vacuum atmosphere, the substrate S may be transferred among the first to third process chambers 1410, 1420, and 1430 by the transfer chamber 1320.

In some embodiments, to form a tunnel barrier layer, the substrate S may be moved sequentially to the third process chamber 1430, the first process chamber 1410, the third process chamber 1430, and the second process chamber 1420 by the transfer chamber 1320. Based on a path of the substrate S, the deposition process for depositing the first metal layer (31 of FIG. 4B) in the third process chamber 1430, the oxidation process for oxidizing the first metal layer in the first process chamber 1410, the deposition process for depositing the second metal layer (35 of FIG. 4D) in the third process chamber 1430, and the oxidation process for oxidizing the second metal layer 35 in the second process chamber 1420 may be performed as in-situ processes.

According to inventive concepts, the oxidation process for oxidizing the first metal layer at a relatively low temperature and the oxidation process for oxidizing the second metal layer 35 at a relatively high temperature may be performed in different chambers. Since the low-temperature oxidation process and the high-temperature oxidation process are performed in different chambers each maintaining a uniform temperature, dispersion between different memory devices on the substrate S due to a non-uniform temperature of an oxidation process may be reduced and/or prevented. In addition, compared to a case when the low-temperature oxidation process and the high-temperature oxidation process are performed in the same chamber, since heating and cooling processes for controlling the temperature in a chamber are not necessary, productivity of equipment may be increased.

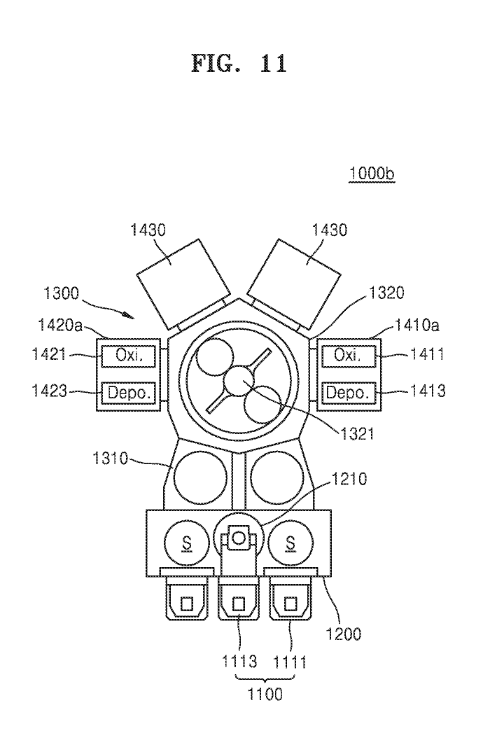

FIG. 10 is a schematic diagram of a semiconductor manufacturing apparatus 1000a according to other embodiments of inventive concepts. Except for the configuration of a first process chamber 1410a, the semiconductor manufacturing apparatus 1000a illustrated in FIG. 10 may have the same or similar configuration as that of the semiconductor manufacturing apparatus 1000 illustrated in FIG. 9. In FIG. 10, the descriptions given above in relation to FIG. 9 will be omitted or briefly provided.

Referring to FIG. 10, the first process chamber 1410a may operate at a first temperature and may perform a deposition process for depositing a metal layer on the substrate S and an oxidation process for oxidizing the substrate S. The first process chamber 1410a may include the oxidation unit 1411 for performing the oxidation process and a deposition unit 1413 for performing the deposition process. In some embodiments, the deposition unit 1413 may perform a DC sputtering process.

The first process chamber 1410a may be configured to perform the deposition process described above in relation to FIG. 4B to deposit the first metal layer (31 of FIG. 4B) and the oxidation process described above in relation to FIG. 4C to oxidize the first metal layer. That is, the deposition process for depositing the first metal layer and the oxidation process for oxidizing the first metal layer may be performed in the same chamber. Furthermore, the first process chamber 1410a may be configured to perform the deposition process described above in relation to FIG. 4D to deposit the second metal layer (35 of FIG. 4D).

In some embodiments, to form a tunnel barrier layer, the transfer chamber 1320 may move the substrate S sequentially to the first process chamber 1410a and the second process chamber 1420. Based on a path of the substrate S, the deposition process for depositing the first metal layer, the oxidation process for oxidizing the first metal layer, and the deposition process for depositing the second metal layer 35 in the first process chamber 1410a and the oxidation process for oxidizing the second metal layer 35 in the second process chamber 1420 may be performed as in-situ processes.

FIG. 11 is a schematic diagram of a semiconductor manufacturing apparatus 1000b according to other embodiments of inventive concepts. Except for the configuration of a second process chamber 1420a, the semiconductor manufacturing apparatus 1000b illustrated in FIG. 11 may have the same or similar configuration as that of the semiconductor manufacturing apparatus 1000a illustrated in FIG. 10. In FIG. 11, the descriptions given above in relation to FIG. 10 will be omitted or briefly provided.

Referring to FIG. 11, the second process chamber 1420a may operate at a second temperature and may perform a deposition process for depositing a metal layer on the substrate S and an oxidation process for oxidizing the substrate S. The second process chamber 1420a may include an oxidation unit 1421 for performing the oxidation process and a deposition unit 1423 for performing the deposition process. In some embodiments, the deposition unit 1423 may perform a DC sputtering process.

The second process chamber 1420a may be configured to perform the deposition process described above in relation to FIG. 4D to deposit the second metal layer (35 of FIG. 4D) and the oxidation process described above in relation to FIG. 4E to oxidize the second metal layer 35. That is, the deposition process for depositing the second metal layer 35 and the oxidation process for oxidizing the second metal layer 35 may be performed in the same chamber.

Since each of the first and second process chambers 1410a and 1420a is configured to perform a deposition process and an oxidation process, a footprint of the semiconductor manufacturing apparatus 1000 may be reduced.

In some embodiments, to form a tunnel barrier layer, the transfer chamber 1320 may move the substrate S sequentially to the first process chamber 1410a and the second process chamber 1420a. Based on a path of the substrate S, the deposition process for depositing the first metal layer (31 of FIG. 4B) and the oxidation process for oxidizing the first metal layer in the first process chamber 1410a and the deposition process for depositing the second metal layer 35 and the oxidation process for oxidizing the second metal layer 35 in the second process chamber 1420a may be performed as in-situ processes.

In some embodiments, as described above in relation to FIGS. 5A and 5B, the first process chamber 1410a may form a first interlayer by repeatedly performing a metal layer deposition process and a metal layer oxidation process at least two times.

In some embodiments, as described above in relation to FIGS. 6A and 6B, the second process chamber 1420a may form a second interlayer by repeatedly performing a metal layer deposition process and a metal layer oxidation process at least two times.

FIG. 12 is a cross-sectional view of a process chamber 1500 of a semiconductor manufacturing apparatus, according to some embodiments of inventive concepts.

Referring to FIG. 12, the process chamber 1500 may include a processing vessel 1501, a substrate holder 1510, a heater 1520, a metal target 1530, and a gas supplier 1540. The process chamber 1500 may be the first process chamber 1410 or 1410a described above in relation to FIGS. 9 to 11, or the second process chamber 1420 or 1420a described above in relation to FIGS. 9 to 11.

The processing vessel 1501 may provide a processing space therein, and a gate 1503 through which the substrate S to be processed enters may be provided in a side wall of the processing vessel 1501.

The substrate holder 1510 may be provided in the processing space and may support the substrate S. The substrate holder 1510 may include a base 1511 and a chuck 1513 provided on the base 1511 to support the substrate S. The chuck 1513 may be configured as an electrostatic chuck for adsorbing the substrate S thereon by using electrostatic force.

The substrate holder 1510 may be configured to be rotated or lifted in connection with a driving mechanism 1515. The driving mechanism 1515 may include a driving shaft 1517 and a driving motor 1519 connected to an end of the driving shaft 1517 to generate driving force for rotating or lifting the driving shaft 1517.

The heater 1520 may be provided in the processing space and may heat the substrate S. The heater 1520 may be provided in the substrate holder 1510. The heater 1520 may be configured to heat the substrate S based on, for example, lamp radiation, Joule resistance heating, induction heating, or microwave heating. For example, the heater 1520 may include an electric circuit for resistive heating. For example, the heater 1520 may be configured to heat the substrate S in the oxidation process described above in relation to FIG. 4E to oxidize the second metal layer (35 of FIG. 4D). The heater 1520 may be omitted in some cases, for example, when the substrate S is processed at room temperature as in the first process chamber 1410a illustrated in FIG. 11.

The metal target 1530 may be provided above the substrate holder 1510. The metal target 1530 may be selected based on a metal layer to be deposited. For example, the metal target 1530 may be used to form a tunnel barrier layer of a magnetic tunnel junction layer and may include, for example, a Mg target. The number of metal targets 1530 is not limited to two and one or more metal targets 1530 may be provided.

The metal target 1530 may be electrically connected to a target electrode 1531. A power supply 1533 may be connected to the target electrode 1531 and may be a direct current (DC) power supply. A magnet 1535 capable of generating a magnetic field may be provided at a side of the target electrode 1531 opposite to the metal target 1530, and may be connected to a magnet driver 1537.

The gas supplier 1540 may supply a gas into the processing vessel 1501 through an inlet port 1505 provided on the processing vessel 1501. The gas supplier 1540 may include a gas source 1541 and a flow rate controller 1543 such as a mass flow controller. The gas of the gas source 1541 may be supplied through the flow rate controller 1543 to the inlet port 1505.

In some embodiments, the gas supplier 1540 may supply a certain gas into the processing vessel 1501 to perform a sputtering process. The gas supplier 1540 may supply a gas, e.g., an inert gas, which may be excited in the processing vessel 1501 during the sputtering process. When the gas is supplied into the processing vessel 1501 by the gas supplier 1540 and a voltage is applied to the metal target 1530 by the power supply 1533, the gas supplied into the processing vessel 1501 may be excited. In addition, when the magnet 1535 is driven by the magnet driver 1537, a magnetic field may be generated around the metal target 1530 and thus plasma may be concentrated near the metal target 1530. As cations in plasma collide with the metal target 1530, a material of the metal target 1530 may be released. The metal target 1530 and/or the material released from the metal target 1530 may be deposited on the substrate S.

In some embodiments, the gas supplier 1540 may supply a certain gas into the processing vessel 1501 to perform an oxidation process. The gas supplier 1540 may supply an oxygen gas and an inert gas for controlling a pressure of the oxidation process, into the processing vessel 1501.

Although not illustrated, each of the semiconductor manufacturing apparatuses 1000, 1000a, and/or 1000b may further include a controller and a memory connected through a bus. The memory may be a nonvolatile memory, such as a flash memory, a phase-change random access memory (PRAM), a magneto-resistive RAM (MRAM), a resistive RAM (ReRAM), or a ferro-electric RAM (FRAM), or a volatile memory, such as a static RAM (SRAM), a dynamic RAM (DRAM), or a synchronous DRAM (SDRAM). The controller may be, a central processing unit (CPU), a processor, an application-specific integrated circuit (ASIC), or another suitable hardware processing unit, that when, executing instructions stored in the memory, configures the controller as a special purpose controller for controlling the semiconductor manufacturing apparatuses 1000, 1000a, and/or 1000b and process chamber 1500 to perform one or more of the above-described magnetic tunnel junction layer manufacturing processes described above in relation to the semiconductor manufacturing apparatuses 1000, 1000a, and/or 1000b and the process chamber 1500 in FIG. 12.

While inventive concepts has been particularly shown and described with reference to embodiments thereof, it will be understood that various changes in form and details may be made therein without departing from the spirit and scope of the following claims.

1. A semiconductor manufacturing apparatus comprising:
a transfer chamber configured to transfer a substrate;
a first process chamber connected to the transfer chamber, the first process chamber configured to perform a first oxidation process for oxidizing a metal layer on the substrate at a first temperature; and
a second process chamber connected to the transfer chamber, the second process chamber configured to perform a second oxidation process for oxidizing a metal layer on the substrate at a second temperature higher than the first temperature.

2. The semiconductor manufacturing apparatus of claim 1, wherein the first process chamber is configured to operate at room temperature.

3. The semiconductor manufacturing apparatus of claim 1, wherein the first process chamber is further configured to perform a first deposition process for depositing a metal layer on the substrate.

4. The semiconductor manufacturing apparatus of claim 1, wherein
the first process chamber includes a first gas supplier for supplying an oxygen gas into the first process chamber, and
the first gas supplier is configured to supply the oxygen gas at a flow rate between 0.01 sccm and 10 sccm to perform the first oxidation process.

5. The semiconductor manufacturing apparatus of claim 1, wherein the second process chamber is configured to operate at the second temperature between 50° C. and 400° C.

6. The semiconductor manufacturing apparatus of claim 1, wherein the second process chamber is further configured to perform a second deposition process for depositing a metal layer on the substrate.

7. The semiconductor manufacturing apparatus of claim 1, wherein
the second process chamber includes a second gas supplier for supplying an oxygen gas into the second process chamber, and
wherein the second gas supplier is configured to supply the oxygen gas at a flow rate between 0.1 sccm to 100 sccm to perform the second oxidation process.

8. The semiconductor manufacturing apparatus of claim 1, wherein
the second process chamber includes a substrate holder for supporting the substrate, and
the substrate holder includes a heater.

9. The semiconductor manufacturing apparatus of claim 1, further comprising:
a third process chamber connected to the transfer chamber, wherein
the third process chamber is configured to perform a deposition process for depositing a metal layer on the substrate.

10. A semiconductor manufacturing apparatus comprising:
a first process chamber configured to operate at a first temperature, the first process chamber being configured to perform a first oxidation process for oxidizing a first metal layer on a substrate by injecting an oxygen gas into the first process chamber;
a second process chamber configured to operate at a second temperature that is higher than the first temperature, the second process chamber being configured to perform a second oxidation process for oxidizing a second metal layer provided on the oxidized first metal layer by injecting an oxygen gas into the second process chamber, the second metal layer including a same material as the first metal layer; and
a transfer chamber connected to the first process chamber and the second process chamber, the transfer chamber being configured to transfer the substrate from the first process chamber to the second process chamber.

11. The semiconductor manufacturing apparatus of claim 10, wherein the first process chamber is further configured to perform a first deposition process for depositing the first metal layer.

12. The semiconductor manufacturing apparatus of claim 11, wherein the first process chamber is configured to sequentially and repeatedly perform the first deposition process and the first oxidation process at least two times.

13. The semiconductor manufacturing apparatus of claim 10, wherein the second process chamber is further configured to perform a second deposition process for depositing the second metal layer.

14. The semiconductor manufacturing apparatus of claim 13, wherein the second process chamber is configured to sequentially and repeatedly perform the second deposition process and the second oxidation process at least two times.

15. The semiconductor manufacturing apparatus of claim 10, wherein
the first temperature is greater than 20° C. and less than 50° C., and
the second temperature is between 50° C. and 400° C.

16. A method of manufacturing a memory device, the method comprising:
forming a first magnetic layer on a substrate;
forming a first metal layer on the first magnetic layer;
oxidizing the first metal layer at a first temperature to form an oxidized first metal layer;
forming a second metal layer on the oxidized first metal layer, the second metal layer and the first metal layer including a same material; and
oxidizing the second metal layer at a second temperature that is higher than the first temperature.

17. The method of claim 16, wherein
the oxidizing the first metal layer is performed in a first process chamber, and
the oxidizing the second metal layer is performed in a second process chamber that is different from the first process chamber.

18. The method of claim 17, wherein the oxidizing the first metal layer includes supplying an oxygen gas into the first process chamber at a flow rate between 0.01 sccm and 10 sccm.

19. The method of claim 17, wherein the oxidizing the second metal layer includes supplying an oxygen gas into the second process chamber at a flow rate between 0.1 sccm and 100 sccm.

20. The method of claim 16, wherein the forming the first metal layer and the oxidizing of the first metal layer are performed in a same chamber.

21.-27. (canceled)
